(19) United States
(12) Patent Application Publication
(10) Pub. No.: US 2026/0239562 A1
(43) Pub. Date: Aug. 13, 2026

(54) THERMAL MANAGEMENT FOR AN ELECTRICAL COMPONENT

(71) Applicant: TE Connectivity Solutions GmbH, Schaffhausen (CH)

(72) Inventors: Alan Weir Bucher, Middletown, PA (US); David Patrick Orris, Middletown, PA (US); Yongyao Cai, Middletown, PA (US)

(21) Appl. No.: 19/051,459

(22) Filed: Feb. 12, 2025

(51) Int. Cl. H05K 7/20

(52) U.S. Cl. CPC H05K 7/20254; H05K 7/20272

(57) ABSTRACT

A heat transfer assembly includes a cold plate that includes a cold plate body to form a fluid cavity configured to receive coolant. The cold plate includes a fluid inlet and a fluid outlet in flow communication with the fluid cavity. The heat transfer assembly includes a thermal bridge coupled to the cold plate. The thermal bridge includes an upper thermal interface and a lower thermal interface. The thermal bridge includes a plurality of interleaved plates arranged in a plate stack with the plates being movable relative to each other in the plate stack. The lower thermal interface configured to be in thermal communication with an electrical component to dissipate heat from the electrical component. The thermal bridge extends through the cold plate body with the upper thermal interface exposed in the fluid cavity for interfacing with the coolant.

### BACKGROUND OF THE INVENTION

The subject matter herein relates generally to thermal management for electrical components.

It may be desirable to transfer thermal energy (or heat) away from designated components of a system or device. Some systems use electrical components, such as electrical connectors, to transmit data and/or electrical power to and from different systems or devices. Some systems use electrical components, such as pluggable modules for transmitting data signals through communication cable(s) in the form of optical signals and/or electrical signals. Some systems use electrical components, such as integrated circuits, for controlling the system. The electrical components define heat generating sources within the system.

A common challenge that confronts developers of electrical systems is heat management. Thermal energy generated by electrical components within a system can degrade performance or even damage components of the system. To dissipate the thermal energy, systems include a thermal component, such as a heat sink, which engages the heat source, absorbs the thermal energy from the heat source, and transfers the thermal energy away. The amount of heat dissipation from such systems may be limited. Some known electrical systems include a cold plate to dissipate heat from the heat generating components to improve heat dissipation compared to heat sinks. However, interfacing the cold plate with the heat generating component (for example, the pluggable I/O module) can be challenging. Additionally, such systems incorporating cold plates typically include multiple thermal interfaces between the heat generating components and the cold plate. Each thermal interface creates a thermal break leading to inefficient heat dissipation.

There is a need for a thermal management system that efficiently transfers thermal energy away from an electrical component.

### BRIEF DESCRIPTION OF THE INVENTION

In one embodiment, a heat transfer assembly is provided and includes a cold plate that includes a cold plate body to form a fluid cavity configured to receive coolant. The cold plate includes a fluid inlet and a fluid outlet in flow communication with the fluid cavity. The heat transfer assembly includes a thermal bridge coupled to the cold plate. The thermal bridge includes an upper thermal interface and a lower thermal interface. The thermal bridge includes a plurality of interleaved plates arranged in a plate stack with the plates being movable relative to each other in the plate stack. The lower thermal interface is configured to be in thermal communication with an electrical component to dissipate heat from the electrical component. The thermal bridge extends through the cold plate body with the upper thermal interface exposed in the fluid cavity for interfacing with the coolant.

In another embodiment, a heat transfer assembly is provided and includes a cold plate that includes a cold plate body to form a fluid cavity configured to receive coolant. The cold plate includes a fluid inlet and a fluid outlet in flow communication with the fluid cavity. The heat transfer assembly includes a thermal bridge coupled to the cold plate. The thermal bridge includes an upper bridge assembly thermally coupled to the cold plate, a lower bridge assembly configured to be thermally coupled to an electrical component, and a spring element between the upper bridge assembly and the lower bridge assembly allowing expansion and compression of the thermal bridge. The upper bridge assembly includes a plurality of upper plates arranged in an upper plate stack. Each upper plate has a front end and a rear end. Each upper plate has sides between the front end and the rear end. Each upper plate has an inner end and an outer end. The outer ends of the upper plates form an upper thermal interface. The upper bridge assembly extends through the cold plate body with the upper thermal interface exposed in the fluid cavity for interfacing with the coolant. The lower bridge assembly includes a plurality of lower plates arranged in a lower plate stack. Each lower plate has a front end and a rear end. Each lower plate has sides between the front end and the rear end. Each lower plate has an inner end and an outer end. The outer ends of the lower plates are configured to face and thermally couple to the electrical component. The sides of the lower plates face the sides of the upper plates to thermally interface the lower plates with the upper plates. The spring element includes an upper spring member engaging the upper plates and a lower spring member engaging the lower plates to bias the lower plates with an opening force generally away from the upper plates.

In a further embodiment, a communication system is provided and includes an electrical component that includes a thermal surface. The communication system includes a heat transfer assembly thermally coupled to the thermal surface to dissipate heat from the electrical component. The heat transfer assembly includes a cold plate, and a thermal bridge coupled to the cold plate. The cold plate includes a cold plate body to form a fluid cavity configured to receive coolant. The cold plate includes a fluid inlet and a fluid outlet in flow communication with the fluid cavity. The thermal bridge includes an upper thermal interface and a lower thermal interface. The thermal bridge includes a plurality of interleaved plates arranged in a plate stack with the plates being movable relative to each other in the plate stack. The lower thermal interface is configured to be in thermal communication with the thermal surface of the electrical component to dissipate heat from the electrical component. The thermal bridge extends through the cold plate body with the upper thermal interface exposed in the fluid cavity for interfacing with the coolant.

### BRIEF DESCRIPTION OF THE DRAWINGS

FIG. 1 is a front perspective view of a communication system formed in accordance with an exemplary embodiment.

FIG. 2 is a top perspective view of the heat transfer assembly in accordance with an exemplary embodiment.

FIG. 3 is a bottom perspective view of the heat transfer assembly in accordance with an exemplary embodiment.

FIG. 4 is an exploded view of the heat transfer assembly in accordance with an exemplary embodiment.

FIG. 5 is a front perspective view of a portion of the thermal bridge in accordance with an exemplary embodiment.

FIG. 6 is a sectional view of the thermal bridge in accordance with an exemplary embodiment.

FIG. 7 is a side view of a portion of the thermal bridge in accordance with an exemplary embodiment.

FIG. 8 illustrates plate pairs, including upper plates and lower plates arranged relative to each other in the plate pairs in accordance with an exemplary embodiment.

FIG. 9 illustrates plate pairs, including upper plates and lower plates arranged relative to each other in the plate pairs in accordance with an exemplary embodiment.

FIG. 10 is a top perspective view of a portion of the heat transfer assembly in accordance with an exemplary embodiment with the cold plate shell removed to illustrate the thermal bridge relative to the cold plate base.

FIG. 11 is an cross-sectional view of a portion of the heat transfer assembly in accordance with an exemplary embodiment with the cold plate shell removed to illustrate the thermal bridge relative to the cold plate base.

FIG. 12 is a sectional view of a portion of the heat transfer assembly in accordance with an exemplary embodiment.

FIG. 13 is a cross-sectional view of the heat transfer assembly in accordance with an exemplary embodiment.

FIG. 14 is a cross-sectional view of a portion of the heat transfer assembly in accordance with an exemplary embodiment showing coolant channels through the heat transfer assembly.

FIG. 15 is a cross-sectional view of a portion of the heat transfer assembly in accordance with an exemplary embodiment.

FIG. 16 is a top perspective view of the heat transfer assembly in accordance with an exemplary embodiment.

FIG. 17 is a sectional view of the heat transfer assembly shown in FIG. 16 in accordance with an exemplary embodiment.

FIG. 18 is a top perspective, exploded view of the heat transfer assembly shown in FIG. 16 in accordance with an exemplary embodiment.

FIG. 19 is a bottom perspective, exploded view of the heat transfer assembly shown in FIG. 16 in accordance with an exemplary embodiment.

FIG. 20 is a sectional view of a portion of the heat transfer assembly 50 in accordance with an exemplary embodiment.

### DETAILED DESCRIPTION OF THE INVENTION

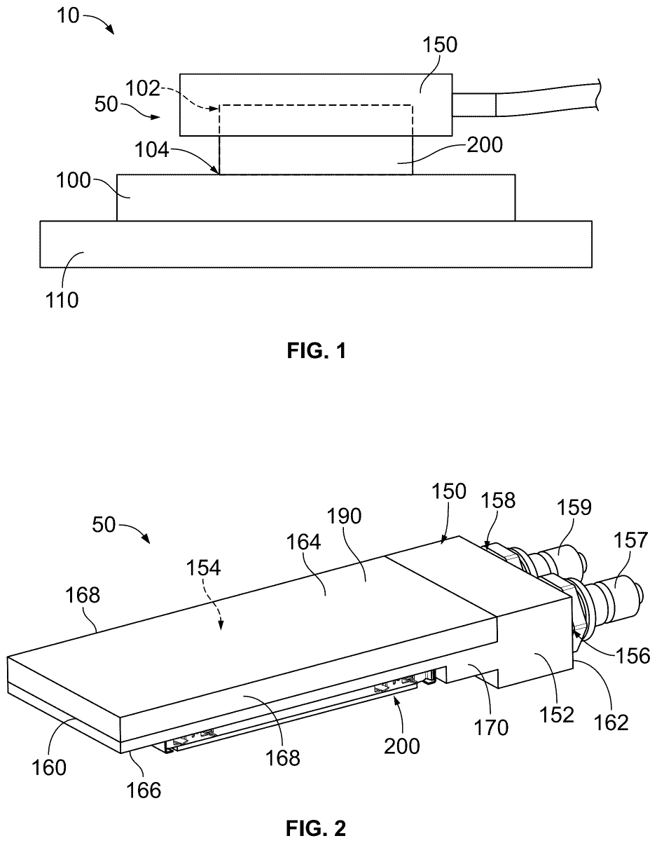

FIG. 1 is a front perspective view of a communication system 10 formed in accordance with an exemplary embodiment. The communication system 10 includes a heat transfer assembly 50 with heat dissipating components for thermal management of one or more electrical components 100 of the communication system 10. The heat transfer assembly 50 is thermally coupled to the electrical component(s) 100 to dissipate heat from the electrical component(s) 100 when mated therewith.

In an exemplary embodiment, the heat transfer assembly 50 includes a cold plate 150 and a thermal bridge 200 coupled to the cold plate 150. The cold plate 150 is a conductive cooling device. In an exemplary embodiment, the cold plate 150 is a liquid cold plate using liquid coolant to dissipate heat. The cold plate 150 allows fluid circulation therethrough to dissipate heat from the communication system 10. In an exemplary embodiment, the thermal bridge 200 is in direct thermal communication with the liquid coolant for efficient thermal transfer between the thermal bridge 200 and the coolant. For example, a portion of the thermal bridge 200 extends into an interior of the cold plate 150 for directly interfacing with the coolant. The coolant removes heat directly from the thermal bridge 200, without an additional interface between the thermal bridge 200 and the coolant. The cold plate 150 and the thermal bridge 200 are sealed to contain the coolant and allow the coolant to circulate through the heat transfer assembly.

The thermal bridge 200 is configured to be thermally coupled to the cold plate 150, such as the coolant in the cold plate 150, at an upper thermal interface 102 at a top of the thermal bridge 200. The thermal bridge 200 is configured to be thermally coupled to the electrical component 100 at a lower thermal interface 104 at a bottom of the thermal bridge 200. The thermal bridge 200 thermally connects the electrical component 100 and the cold plate 150 to transport heat from the electrical component 100.

In an exemplary embodiment, the thermal bridge 200 is compressible to allow conformance of the lower thermal interface 104 with the electrical component 100. The lower thermal interface 104 is conformable to a shape of the electrical component 100 for efficient thermal transfer therebetween. For example, the thermal bridge 200 may be a stacked plate-like structure wherein the individual plates are movable relative to each other to conform to the electrical component 100. Thermal grease or other thermal interface materials may be provided at the lower thermal interface 104 to enhance thermal transfer between the thermal bridge 200 and the electrical component 100.

The electrical component 100 may be mounted to a circuit board 110. In various embodiments, the electrical component 100 may be a communication connector, such as a receptacle connector, a header connector, a plug connector, or another type of communication connector. In other various embodiments, the electrical component 100 may be an electronic package, such as an integrated circuit. In other various embodiments, the electrical component 100 may be a pluggable module, such as an I/O transceiver module. Other types of electrical components may be provided in alternative embodiments.

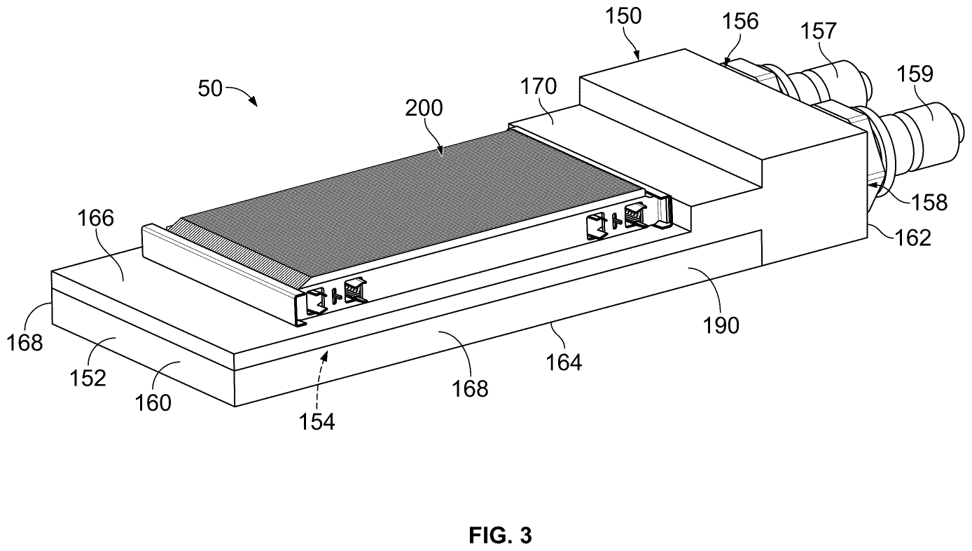

FIG. 2 is a top perspective view of the heat transfer assembly 50 in accordance with an exemplary embodiment. FIG. 3 is a bottom perspective view of the heat transfer assembly 50 in accordance with an exemplary embodiment. The heat transfer assembly 50 includes the cold plate 150 and the thermal bridge 200.

The cold plate 150 includes a cold plate body 152 forming a fluid cavity 154 configured to receive the coolant. The cold plate body 152 may be a multi-piece body, such as including a cold plate base 170 at the bottom and a cold plate shell 190 at the top. The cold plate body 152 may include additional body elements in alternative embodiments. In other various embodiments, the cold plate body 152 may be a single piece body. In an exemplary embodiment, the cold plate body 152 is manufactured from a thermally conductive material, such as a metal material, such as aluminum or copper. The cold plate body 152 may be die cast, molded, stamped, or formed by other forming processes. In other various embodiments, the cold plate body 152 may be manufactured from a plastic material, such as being a molded plastic body. The plastic material may be a thermally conductive plastic material.

The cold plate 150 includes a fluid inlet 156 having a fluid inlet fitting 157 and a fluid outlet 158 having a fluid outlet fitting 159. The coolant flows into the fluid cavity 154 through the fluid inlet 156. The coolant flows out of the fluid cavity 154 through the fluid outlet 158. In an exemplary embodiment, the thermal bridge 200 extends through the cold plate body 152 into the fluid cavity 154. The thermal bridge 200 interfaces with the coolant in the fluid cavity 154 to dissipate heat from the thermal bridge 200.

The cold plate 150 extends between a front 160 and a rear 162. The cold plate 150 includes a top 164 and a bottom 166. The cold plate 150 has sides 168 between the top 164 and the bottom 166. The cold plate 150 may be rectangular. However, the cold plate 150 may have other shapes in alternative embodiments. The cold plate 150 may include other sides, walls and/or surfaces in other embodiments.

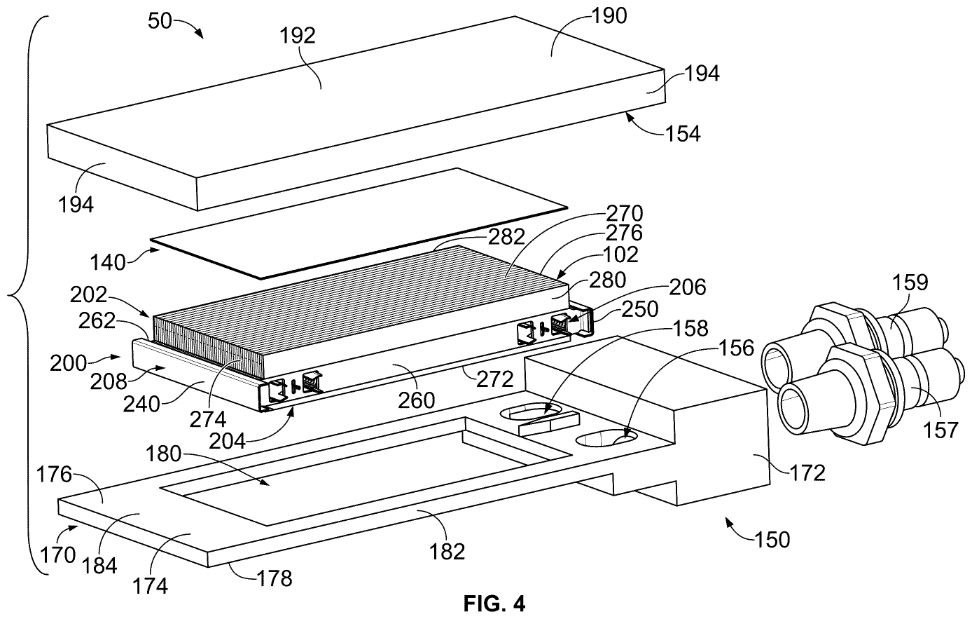

FIG. 4 is an exploded view of the heat transfer assembly 50 in accordance with an exemplary embodiment. The heat transfer assembly 50 includes the cold plate 150 and the thermal bridge 200. The thermal bridge 200 is configured to be thermally coupled to the cold plate 150. For example, an upper portion of the thermal bridge 200, at the upper thermal interface 102, is configured to be received in an interior of the cold plate 150 for directly interfacing with the coolant. In an exemplary embodiment, the heat transfer assembly 50 includes a fluid barrier 140 configured to be coupled to the thermal bridge 200 and/or the cold plate 150 to provide a fluid seal for the heat transfer assembly 50.

In the illustrated embodiment, the cold plate 150 includes the cold plate base 170 and the cold plate shell 190. In an exemplary embodiment, the thermal bridge 200 is configured to be coupled to the cold plate base 170. For example, the thermal bridge 200 may pass through the cold plate base 170 to extend into the fluid cavity 154. The upper portion of the thermal bridge 200 is configured to extend into the fluid cavity 154 in the cold plate shell 190. The cold plate shell 190 is configured to cover the upper portion of the thermal bridge 200.

The cold plate base 170 includes a base portion 172 and a support portion 174 extending from the base portion 172. The base portion 172 may be located at a rear of the cold plate base 170 and the support portion 174 may be located at a front of the cold plate base 170. Other locations are possible in alternative embodiments. In the illustrated embodiment, the base portion 172 is thicker than the support portion 174. The base portion 172 may be generally box shaped. However, the base portion 172 may have other shapes in alternative embodiments. In the illustrated embodiment, the support portion 174 is generally planar. For example, the support portion 174 may be plate-like. The support portion 174 may have other shapes in alternative embodiments.

In an exemplary embodiment, the fluid inlet 156 and the fluid outlet 158 pass through the base portion 172. The fluid inlet 156 and the fluid outlet 158 may be a channel to the support portion 174 to allow the coolant flow into and out of the fluid cavity 154. The base portion 172 receives the fluid inlet fitting 157 and the fluid outlet fitting 159. For example, the inlet and outlet fittings 157, 159 may be coupled to the rear of the base portion 172. The inlet and outlet fittings 157, 159 may be threadably coupled to the base portion 172. The inlet and outlet fittings 157, 159 may be attached by other means in alternative embodiments. In an exemplary embodiment, the inlet and outlet fittings 157, 159 have sealed interfaces with the base portion 172.

The support portion 174 includes an upper surface 176 and a lower surface 178. The cold plate shell 190 is configured to be coupled to the upper surface 176. For example, the fluid cavity 154 is defined between the cold plate shell 190 and the upper surface 176 of the support portion 174. In an exemplary embodiment, the support portion 174 of the cold plate base 170 includes an opening 180 passing therethrough. The opening 180 is surrounded by side walls 182 and end walls 184. The opening 180 is sized and shaped to receive the thermal bridge 200. The thermal bridge 200 is configured to be coupled to the support portion 174. For example, the thermal bridge 200 may be coupled to the lower surface 178 of the support portion 174 and/or the edges surrounding the opening 180. A portion of the thermal bridge 200 may extend above the upper surface 176 into the fluid cavity 154 to interface with the coolant in the fluid cavity 154.

The cold plate shell 190 is configured to be coupled to the cold plate base 170 to form the fluid cavity 154. The cold plate shell 190 covers the thermal bridge 200. In an exemplary embodiment, the cold plate shell 190 includes an outer wall 192 and side walls 194 extending from the outer wall 192. In the illustrated embodiment, the cold plate shell 190 is generally box shaped. However, the cold plate shell 190 may have other shapes in alternative embodiments. The outer wall 192 and the side walls 194 surrounds the fluid cavity 154. The cold plate base 170 forms a bottom of the fluid cavity 154. A portion of the thermal bridge 200 may close off a portion of the bottom of the fluid cavity 154. For example, the thermal bridge 200 may close off the opening 180 and the fluid barrier 140 may seal the thermal bridge 200 at the opening 180.

In an exemplary embodiment, the thermal bridge 200 includes an upper bridge assembly 202 and a lower bridge assembly 204. In an exemplary embodiment, the thermal bridge 200 includes a spring element 206 between the upper and lower bridge assemblies 202, 204 and a bridge frame 208 for holding the upper and lower bridge assemblies 202, 204 together. The lower bridge assembly 204 is configured to be coupled to and thermally engage the electrical component 100. The upper bridge assembly 202 is configured to be coupled to and thermally engage the cold plate 150. In an exemplary embodiment, the upper bridge assembly 204 is configured to transfer heat to the coolant. For example, a portion of the upper bridge assembly 202 is received in the fluid cavity 154 to interface directly with the coolant. The upper bridge assembly 202 is in thermal communication with the lower bridge assembly 204 and transfers heat away from the lower bridge assembly 204 to cool the electrical component 100.

The spring element(s) 206 biases the upper and lower bridge assemblies 202, 204 apart. The upper and lower bridge assemblies 202, 204 are compressible relative to each other. For example, the upper and lower bridge assemblies 202, 204 are compressible between the electrical component 100 and the cold plate 150 (for example, to compress the spring element 206). In alternative embodiments, the thermal bridge 200 may be provided without the spring elements 206. In such embodiments, the upper bridge assembly 202 may be coupled to the cold plate 150 and the lower bridge assembly 204 may be coupled to the electrical component 100 and the upper and lower bridge assemblies 202, 204 are configured to interface with each other to form the thermal bridge 200. The lower bridge assembly 204 may be bonded or otherwise coupled to the electrical component 100.

The bridge frame 208 provides support for the upper and lower bridge assemblies 202, 204. For example, the bridge frame 208 may surround the outer perimeter or periphery of the thermal bridge 200 to hold the components in an interior space of the bridge frame 208. In an exemplary embodiment, the bridge frame 208 may extend along the sides and ends, leaving the top and bottom to form thermal interfaces with the electrical component 100 and the coolant. Optionally, the bridge frame 208 may provide internal support through the bridge assemblies 202, 204. For example, connecting spars, pins, or other types of internal connecting elements may pass through the bridge assemblies 202, 204.

In an exemplary embodiment, the spring element 206 presses against the upper bridge assembly 202 in a first biasing direction (for example, upward) and the spring element 206 presses against the lower bridge assembly 204 in a second biasing direction (for example, downward). The upper bridge assembly 202 and the lower bridge assembly 204 may be held by the bridge frame 208 in a manner to allow a limited amount of floating movement of the upper bridge assembly 202 and/or the lower bridge assembly 204 relative to the bridge frame 208.

In an exemplary embodiment, the thermal bridge 200 is parallelepiped (for example, generally box shaped). For example, the thermal bridge 200 includes a top 270, a bottom 272, a front 274, a rear 276, a first side 280, and a second side 282. The top 270 may be generally planar. The bottom 272 may be generally planar. The front 274 may be generally planar. The rear 276 may be generally planar. The first side 280 may be generally planar. The second side 282 may be generally planar. However, the thermal bridge 200 may have other shapes in alternative embodiments. The frame structure used to hold the thermal bridge 200 together is defined by the bridge frame 208. The top 270 and the bottom 272 have large surface areas to allows for a large amount of usable external surface area for heat transfer.

In an exemplary embodiment, the bridge assemblies 202, 204 each include a plurality of plates that are arranged together in plate stacks. The plates are interleaved with each other for thermal communication between the upper bridge assembly 202 and the lower bridge assembly 204. The individual plates are movable relative to each other such that the plates may be individually articulated to conform to the electrical component 100. For example, the individual plates may conform to the electrical component 100 at the lower thermal interface 104 for improved contact and/or proximity between the thermal bridge 200 and the electrical component 100. Gaps or spaces may be provided between the plates of the upper and lower bridge assemblies 202, 204 to allow compressive movement of the spring element 206 between the bridge assemblies 202, 204.

In an exemplary embodiment, the bridge frame 208 is manufactured from a plurality of frame elements, which may be connected together to form a supporting structure for the bridge assemblies 202, 204. For example, the frame elements may surround the outer perimeter of the plate stacks. The frame elements may pass through the interior of the plate stacks to hold the bridge assemblies 202, 204. In an exemplary embodiment, the bridge frame 208 includes a front rail 240, a rear rail 250, a first side rail 260 extending between the front and rear rails 240, 250, and a second side rail 262 extending between the front and rear rails 240, 250. The rails may be stamped and formed elements. In an exemplary embodiment, front and rear rails 240, 250 engage the bridge assemblies 202, 204 to limit spreading apart of the bridge assemblies 202, 204 against the opening forces of the spring element 206.

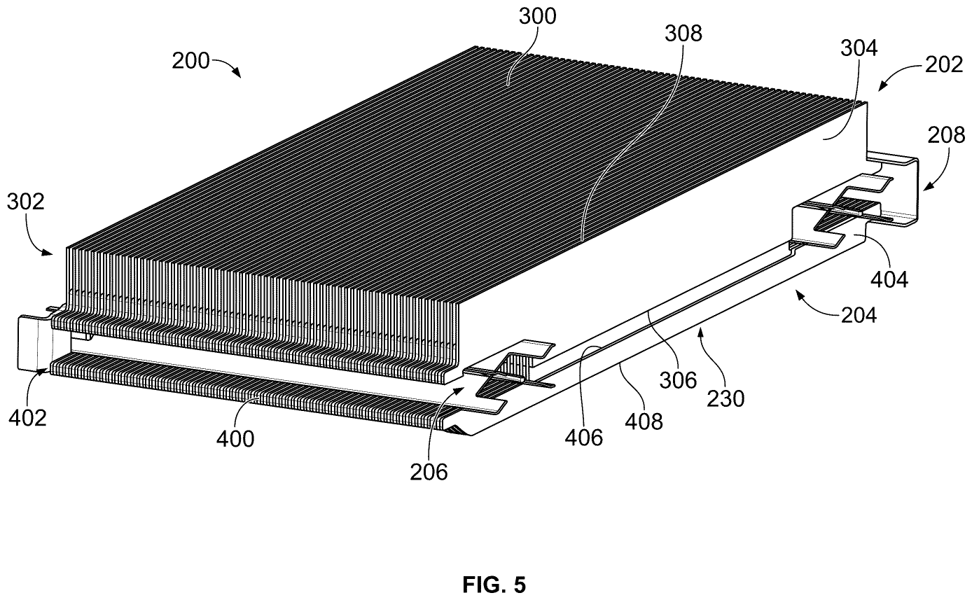

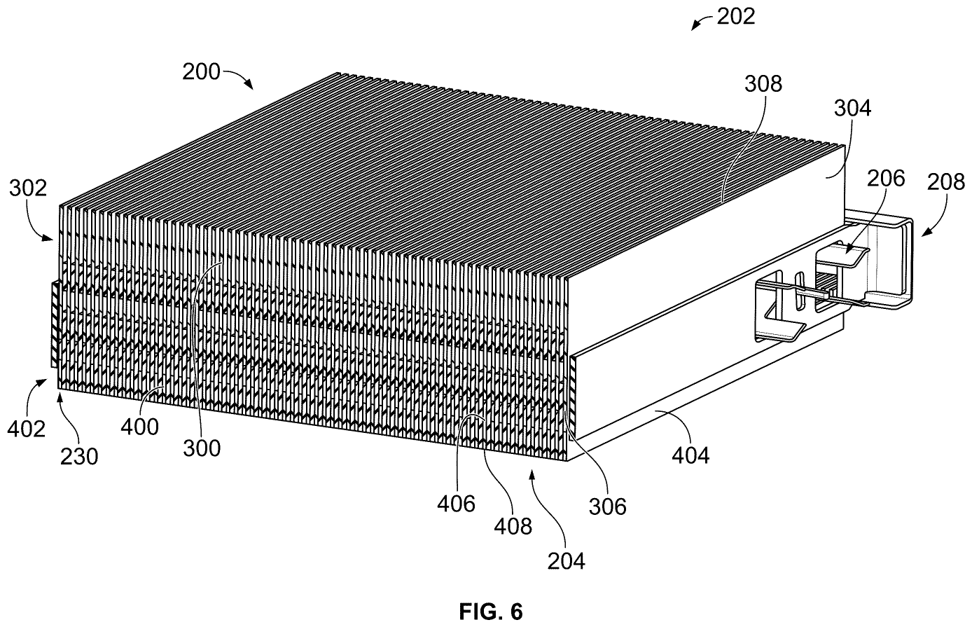

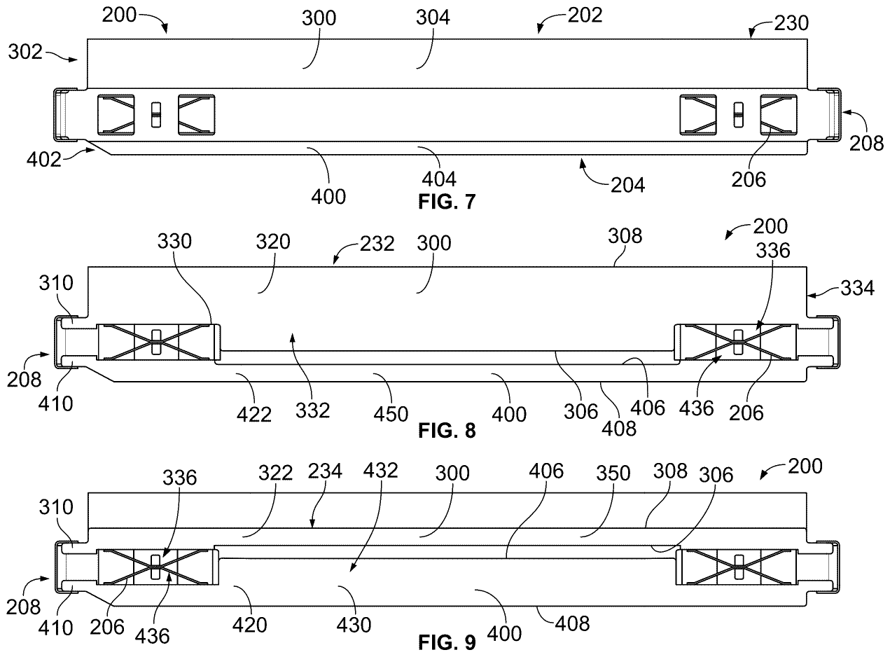

FIG. 5 is a front perspective view of a portion of the thermal bridge 200 in accordance with an exemplary embodiment. FIG. 6 is a sectional view of the thermal bridge 200 in accordance with an exemplary embodiment. FIG. 7 is a side view of a portion of the thermal bridge 200 in accordance with an exemplary embodiment. Portions of the bridge frame 208 are removed in FIGS. 5 and 6 to illustrate the plates of the bridge assemblies 202, 204.

In an exemplary embodiment, the upper bridge assembly 202 includes a plurality of upper plates 300 arranged in an upper plate stack 302. Each upper plate 300 has sides 304 extending between an inner end 306 and an outer end 308 of the upper plate 300. The inner end 306 faces the lower bridge assembly 204. The outer end 308 faces outward, such as toward the top. Optionally, various upper plates 300 may have different shapes, such as different heights and/or different features between the inner end 306 and the outer end 308.

In an exemplary embodiment, the lower bridge assembly 204 includes a plurality of lower plates 400 arranged in a lower plate stack 402. Each lower plate 400 has sides 404 extending between an inner end 406 and an outer end 408 of the lower plate 400. The inner end 406 faces the upper bridge assembly 202. The outer end 408 faces outward, such as toward the electrical component 100 (shown in FIG. 1). Optionally, various lower plates 400 may have different shapes and/or heights between the inner end 406 and the outer end 408.

In an exemplary embodiment, the upper and lower plates 300, 400 are arranged in plate pairs 230. Each plate pair 230 includes one of the upper plates 300 and one of the lower plates 400. The plates 300, 400 in the plate pair 230 are aligned with each other. For example, the upper and lower plates 300, 400 are vertically stacked with the upper plate 300 above the lower plate 400. The plate pairs 230 are stacked together to form the thermal bridge 200 in the stacked arrangement. The bridge frame 208 holds the plate pairs 230 in the stacked arrangement. The spring element 206 is configured to be positioned between the upper and lower plates 300, 400 and spread the upper plates 300 apart from the lower plates 400.

With additional reference to FIGS. 8 and 9, FIGS. 8 and 9 illustrate various plate pairs 230, including upper plates 300 and lower plates 400 arranged relative to each other in the plate pairs 230. FIG. 8 shows a first pair 232. FIG. 9 shows a second pair 234. The upper plates 300 of the first pair 232 are different from the upper plates 300 of the second pair 234. The lower plates 400 of the first pair 232 are different from the lower plates 400 of the second pair 234.

In an exemplary embodiment, the upper plates 300 include upper limit tabs 310 used to position the upper plates 300 relative to the lower plates 400 and/or relative to the bridge frame 208. The upper limit tabs 310 may engage the lower plates 400 and/or the bridge frame 208 to position the upper plates 300 in the upper plate stack 302. The upper limit tabs 310 limit vertical movement of the upper plates 300, such as to limit spreading apart of the upper plates 300 from the lower plates 400. The spring element 206 may press the upper plates 300 outward (for example, upward) until the upper limit tabs 310 bottom out against the lower plates 400, the bridge frame 208, or other intervening structure.

In an exemplary embodiment, the upper plates 300 include upper interface plates 320 (FIG. 8) and upper spacer plates 322 (FIG. 9). The upper spacer plates 322 are located between the upper interface plates 320. The upper interface plates 320 and the upper spacer plates 322 both include upper limit tabs 310.

With reference to FIG. 8, each upper interface plate 320 includes a base 330, an overlapping region 332 at the inner end 306 configured to overlap with adjacent lower plates 400 of the lower bridge assembly 204, and a fluid transfer portion 334 at the outer end 308 configured to interface directly with the coolant fluid. The overlapping region 332 is configured to overlap with adjacent lower plates 400 of the lower bridge assembly 204. The overlapping region 332 provides large surface areas configured to be thermally coupled to the lower plates 400. The fluid transfer portion 334 extends above the base 330 and is configured to be received in the fluid cavity 154. The fluid transfer portion 334 provides a large surface area configured to be thermally coupled to the coolant. For example, both sides of the fluid transfer portion 334 may interface directly with the coolant. In various embodiments, the upper interface plate 320 includes upper gaps 336 that receive a portion of the spring element 206.

With reference to FIG. 9, each upper spacer plate 322 includes a spacer base 350 at the outer end 308. The spacer base 350 may be aligned with the base 330 of the upper interface plate 320. The fluid transfer portions 334 of the upper interface plates 320 extend above the spacer bases 350. The fluid barrier 140 (FIG. 4) may be applied to or coupled to the spacer bases 350, such as at the outer ends 308 of the spacer bases 350.

In an exemplary embodiment, the lower plates 400 include lower limit tabs 410 used to position the lower plates 400 relative to the upper plates 300 and/or relative to the bridge frame 208. The lower limit tabs 410 may engage the upper plates 300 and/or the bridge frame 208 to position the lower plates 400 in the lower plate stack 402. The lower limit tabs 410 limit vertical movement of the lower plates 400, such as to limit spreading apart of the lower plates 400 from the upper plates 300. The spring element 206 may press the lower plates 400 outward (for example, downward) until the lower limit tabs 410 bottom out against the upper plates 300, the bridge frame 208, or other intervening structure.

In an exemplary embodiment, the lower plates 400 include lower interface plates 420 (FIG. 9) and lower spacer plates 422 (FIG. 8). The lower spacer plates 422 are located between the lower interface plates 420. The lower interface plates 420 and the lower spacer plates 422 both include lower limit tabs 410.

With reference to FIG. 9, each lower interface plate 420 includes a base 430 at the outer end 408 and an overlapping regions 432 at the inner end 406 configured to overlap with adjacent upper plates 300 of the upper bridge assembly 202. For example, the overlapping region 432 overlaps with the overlapping regions 332 of the adjacent upper interface plates 320. The overlapping regions 432 provide large surface areas configured to be thermally coupled to the upper interface plates 320. The overlapping regions 432 are configured to overlap the overlapping regions 332 by an overlap distance sufficient to allow efficient thermal transfer between the lower plates 400 and the upper plates 300. The sides of the plates are slidable relative to each other to allow movement between the upper plates 300 and the lower plates 400 and change the overlap distance. In various embodiments, the lower interface plate 420 includes lower gaps 436 that receive a portion of the spring element 206.

With reference to FIG. 8, each lower spacer plate 422 includes a spacer base 450 at the outer end 308. The spacer base 450 may be aligned with the base 430 of the lower interface plate 420. A gap is provided between the lower spacer base 450 and the upper interface plate 320. The gap may be narrowed when the thermal bridge 200 is compressed (for example, when the spring elements 206 are compressed).

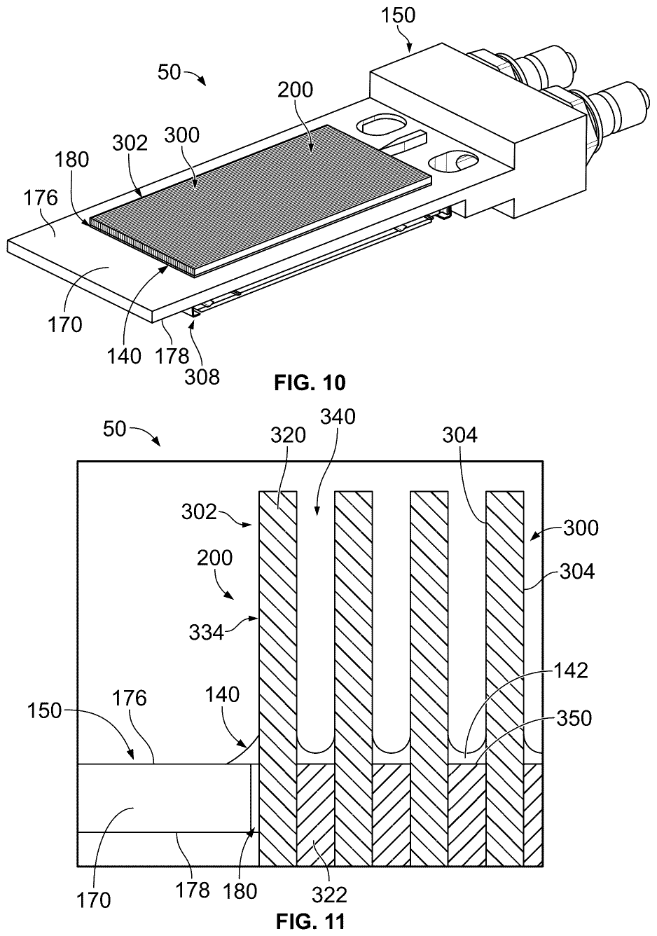

FIG. 10 is a top perspective view of a portion of the heat transfer assembly 50 in accordance with an exemplary embodiment with the cold plate shell 190 removed to illustrate the thermal bridge 200 relative to the cold plate base 170. FIG. 11 is an end view of a portion of the heat transfer assembly 50 in accordance with an exemplary embodiment with the cold plate shell 190 removed to illustrate the thermal bridge 200 relative to the cold plate base 170.

During assembly, the thermal bridge 200 is coupled to the cold plate 150. For example, the thermal bridge 200 is coupled to the lower surface 178 of the cold plate base 170. The thermal bridge 200 may be soldered, welded, fastened, clips, latched, or otherwise coupled to the cold plate base 170. For example, the bridge frame 208 may be coupled to the cold plate base 170. When assembled, the thermal bridge 200 passes through the opening 180. For example, an upper portion of the thermal bridge 200 is located above the upper surface 176. In alternative embodiments, the bridge frame 208 may be located in the opening 180 or located above the cold plate base 170.

In the illustrated embodiment, the fluid transfer portions 334 of the upper interface plates 320 are located above the cold plate base 170 (for example, in the fluid cavity 154). The fluid transfer portions 334 are configured to directly interface with the coolant in the cold plate 150. In an exemplary embodiment, the fluid transfer portions 334 are parallel to each other and spaced apart from each other to define fluid channels 340 between the fluid transfer portions 334. The fluid channels 340 are configured to receive the coolant circulating through the fluid cavity 154 such that the coolant flows along the sides 304 of the fluid transfer portions 334.

The fluid barrier 140 (FIG. 11) may be applied to or coupled to the spacer bases 350, such as at the outer ends 308 of the spacer bases 350. The fluid barrier 140 provides a fluid seal through the plate stack 302 to seal the fluid cavity. For example, the fluid barrier 140 provides a fluid seal between the thermal bridge 200 and the cold plate 150 to seal the fluid cavity. The fluid barrier 140 may be sealed directly to the cold plate 150, such as to the cold plate base 170. For example, the fluid barrier 140 may be sealed to the upper surface 176 and/or at the inner edge defining the opening 180. The fluid barrier 140 may be sealed directly to the upper plates 300. For example, the fluid barrier 140 may be sealed to the sides of the fluid transfer portions 334 and/or the outer ends 308 of the spacer plates 322. The fluid barrier 140 may provide a fluid seal through an interior of the thermal bridge 200 to seal the fluid cavity. For example, the fluid barrier 140 may be sealed between the upper plates 300. In various embodiments, the fluid barrier 140 may be sealed to the sides of the fluid transfer portions 334 and the sides of the spacer plates 322.

In an exemplary embodiment, the fluid barrier 140 includes a solder layer 142 soldered to the upper plates 300 in the plate stack 302. The solder layer 142 may be applied directly to the upper plates 300 and/or the cold plate base 170. The solder layer 142 may partially fill the spaces between upper plates 300.

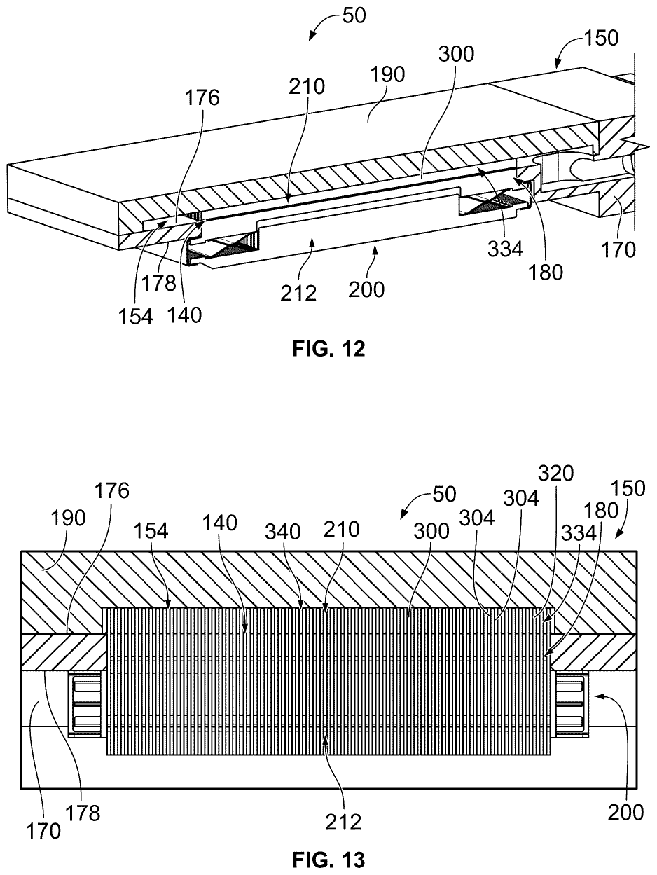

FIG. 12 is a sectional view of a portion of the heat transfer assembly 50 in accordance with an exemplary embodiment. FIG. 13 is a cross-sectional view of the heat transfer assembly 50 in accordance with an exemplary embodiment. FIGS. 12 and 13 show the cold plate shell 190 coupled to the cold plate base 170 and covering the thermal bridge 200.

During assembly, the thermal bridge 200 is coupled to the cold plate 150, such as at the lower surface 178 of the cold plate base 170. The thermal bridge 200 passes through the opening 180 into the fluid cavity 154. The upper portion of the thermal bridge 200 is located above the upper surface 176 of the cold plate base 170 in the fluid cavity 154. The upper portion of the thermal bridge 200 defines a wet portion 210 of the thermal bridge 200. The lower portion of the thermal bridge 200, such as below the fluid barrier 140, defines a dry portion 212 of the thermal bridge 200. The dry portion 212 is configured to interface with the electrical component 100 (FIG. 1).

The fluid transfer portions 334 of the upper interface plates 320 are located above the cold plate base 170 in the fluid cavity 154) to directly interface with the coolant in the cold plate 150. The cold plate shell 190 surrounds the upper portion of the thermal bridge 200 to circulate the coolant in the fluid cavity along the fluid transfer portions 334. For example, the coolant is configured to flow in the fluid channels 340 between the fluid transfer portions 334 along the sides 304 of the fluid transfer portions 334. The coolant dissipates heat from the upper plates 300 to cool the thermal bridge 200 and allow heat transfer from the electrical component.

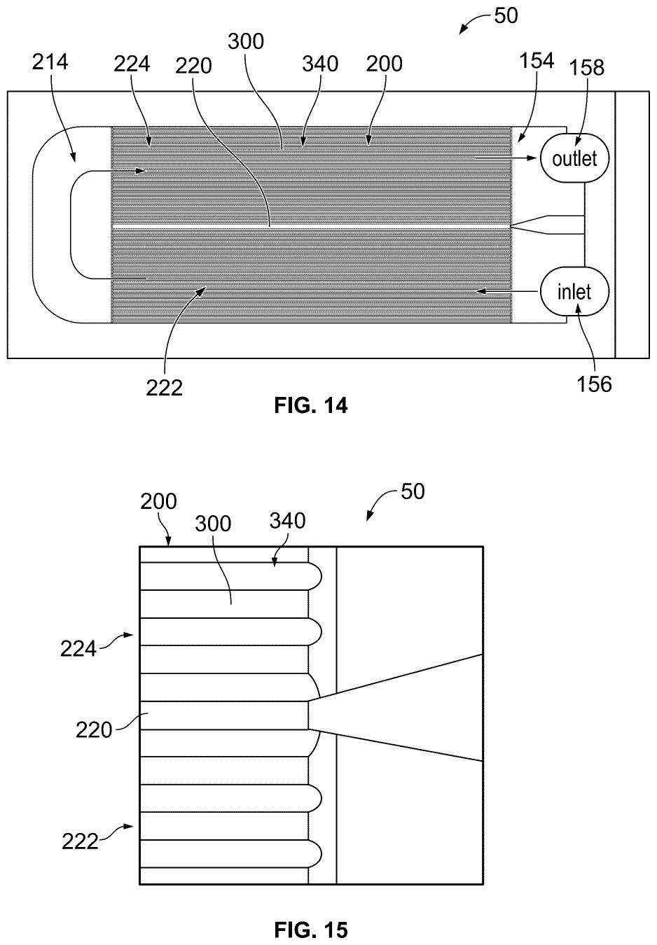

FIG. 14 is a cross-sectional view of a portion of the heat transfer assembly 50 in accordance with an exemplary embodiment showing coolant channels through the heat transfer assembly 50. FIG. 15 is a cross-sectional view of a portion of the heat transfer assembly 50 in accordance with an exemplary embodiment. FIGS. 12 and 13 show the thermal bridge 200 in the fluid cavity 154.

In an exemplary embodiment, the thermal bridge 200 includes a divider 220 dividing the thermal bridge 200 into an inlet side 222 and an outlet side 224. The inlet side 222 is in flow communication with the fluid inlet 156. The outlet side 224 is in flow communication with the fluid outlet 158. The coolant circulates through the fluid cavity 154 and the fluid channels 340 from the fluid inlet 156, through the inlet side 222, through a transition channel 214, through the outlet side 224, to the fluid outlet 158. The divider 220 may be located between two of the upper plates 300. The divider 220 isolates the inlet side 222 form the outlet side 224 restricting fluid flow from the inlet side 222 to the outlet side 224. The coolant is forced to flow along the length of the thermal bridge 200 for efficient heat transfer from the thermal bridge 200.

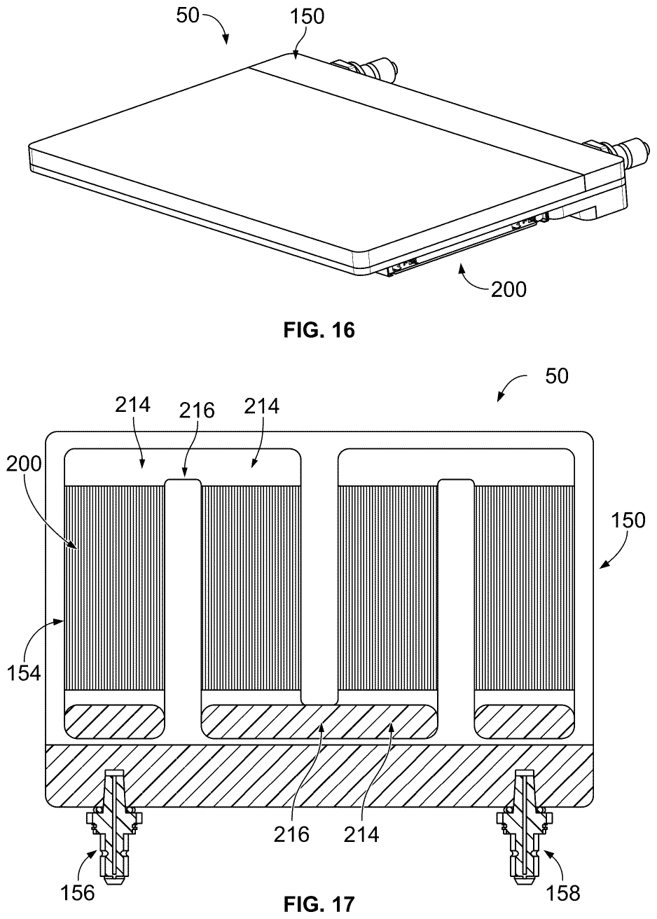

FIG. 16 is a top perspective view of the heat transfer assembly 50 in accordance with an exemplary embodiment. In the illustrated embodiment, the heat transfer assembly 50 includes a plurality of the thermal bridges 200 for interfacing with a plurality of electrical components 100 (FIG. 1). For example, the cold plate 150 is enlarged to receive multiple thermal bridges 200.

FIG. 17 is a sectional view of the heat transfer assembly 50 shown in FIG. 16 in accordance with an exemplary embodiment. In the illustrated embodiment, the cold plate 150 includes a plurality of the fluid cavities 154 connected by connecting channels 216 between the transition channels 214. Coolant is able to flow from the fluid inlet 156 to the fluid outlet 158 through the multiple fluid cavities 154. Each fluid cavity 154 receives the corresponding thermal bridge 200.

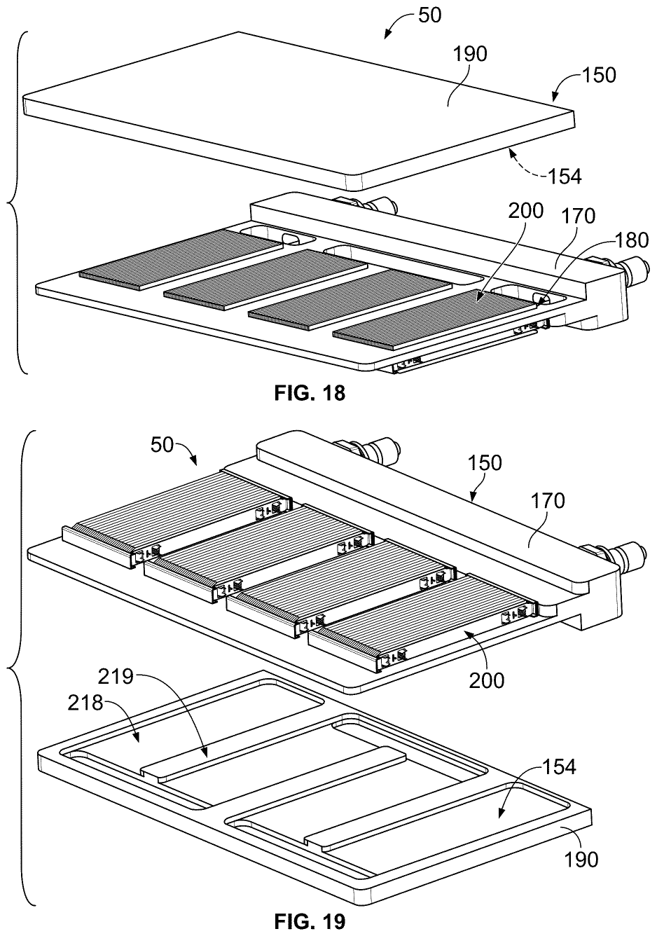

FIG. 18 is a top perspective, exploded view of the heat transfer assembly 50 shown in FIG. 16 in accordance with an exemplary embodiment. FIG. 19 is a bottom perspective, exploded view of the heat transfer assembly 50 shown in FIG. 16 in accordance with an exemplary embodiment. FIGS. 18 and 19 illustrate the thermal bridges 200 coupled to the cold plate base 170 of the cold plate 150.

The thermal bridges 200 are received in corresponding openings 180 in the cold plate base 170. The cold plate shell 190 is configured to cover the thermal bridges 200. The cold plate shell 190 includes individual chambers 218 separated by separating walls 219. The chambers 218 form the individual fluid cavities 154. The chambers 218 receive the corresponding thermal bridges 200.

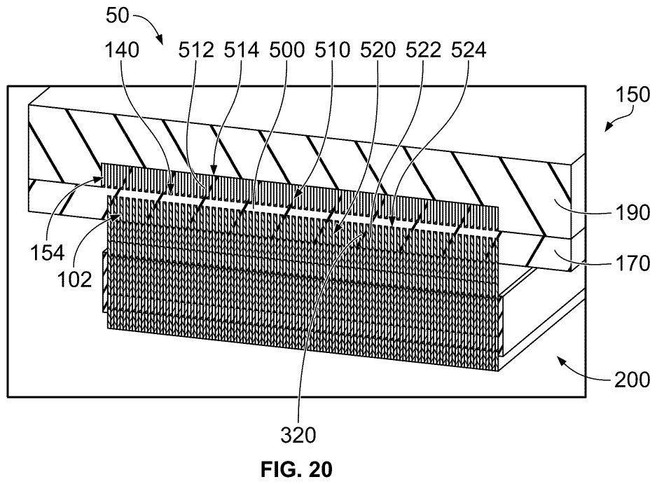

FIG. 20 is a sectional view of a portion of the heat transfer assembly 50 in accordance with an exemplary embodiment. The heat transfer assembly 50 includes the cold plate 150 and the thermal bridge 200. The thermal bridge 200 is configured to be thermally coupled to the cold plate 150. For example, an upper portion of the thermal bridge 200, at the upper thermal interface 102, is configured to be coupled to the cold plate 150. In the illustrated embodiment, the cold plate base 170 forms the fluid barrier 140 to provide a fluid seal between the thermal bridge 200 and the coolant in the fluid cavity 154.

In the illustrated embodiment, the cold plate 150 includes the cold plate base 170 and the cold plate shell 190. The thermal bridge 200 is configured to be coupled to the cold plate base 170. In an exemplary embodiment, the cold plate base 170 includes a base plate 500, an upper transfer fin array 510 above the base plate 500, and a lower transfer fin array 520 below the plate 500. The upper transfer fin plate 510 includes a plurality of upper heat transfer fins 512 arranged in parallel to each other and spaced apart by gaps 514. The upper heat transfer fins 512 are located in the fluid cavity 154 to interface with the coolant. The lower transfer fin array 520 includes a plurality of lower heat transfer fins 522 arranged in parallel to each other and spaced apart by gaps 524. The lower heat transfer fins 522 are exposed at the bottom of the cold plate base 170.

The upper portion of the thermal bridge 200 is configured to interface with the lower transfer fin array 520. For example, the upper interface plates 320 are received in the gaps 524 such that the sides of the upper interface plates 320 face and may interface with the sides of the lower heat transfer fins 522. The upper interface plates 320 and the lower heat transfer fins 522 have overlapping regions that provide large surface areas configured to be thermally coupled to provide an efficient thermal interface and transfer between the thermal bridge 200 and the cold plate 150.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function void of further structure.

What is claimed is:

1. A heat transfer assembly comprising:
a cold plate including a cold plate body forming a fluid cavity configured to receive coolant, the cold plate including a fluid inlet and a fluid outlet in flow communication with the fluid cavity; and
a thermal bridge coupled to the cold plate, the thermal bridge including an upper thermal interface and a lower thermal interface, the thermal bridge including a plurality of interleaved plates arranged in a plate stack with the plates being movable relative to each other in the plate stack, the lower thermal interface configured to be in thermal communication with an electrical component to dissipate heat from the electrical component, the thermal bridge extending through the cold plate body with the upper thermal interface exposed in the fluid cavity for interfacing with the coolant.

2. The heat transfer assembly of claim 1, wherein the plate stack includes a wet portion in the fluid cavity in fluid communication with the coolant and a dry portion outside of the fluid cavity isolated from the coolant.

3. The heat transfer assembly of claim 1, wherein the cold plate body includes a cold plate base and a cold plate shell coupled to the cold plate base, the fluid cavity defined between the cold plate base and the cold plate shell, the cold plate shell covering the thermal bridge.

4. The heat transfer assembly of claim 3, wherein the cold plate base includes an opening, the thermal bridge passing through the opening to interface with the electrical component and the coolant.

5. The heat transfer assembly of claim 4, wherein an upper portion of the plate stack is located above the cold plate body in the fluid cavity, a lower portion of the plate stack is located below the cold plate body to interface with the electrical component.

6. The heat transfer assembly of claim 1, wherein the plates of the plate stack include fluid transfer portions in the fluid cavity in flow communication with the coolant.

7. The heat transfer assembly of claim 6, wherein the thermal bridge includes fluid channels between the fluid transfer portions, the fluid channels configured to receive the coolant flowing between the fluid inlet in the fluid outlet.

8. The heat transfer assembly of claim 1, wherein the thermal bridge includes a fluid barrier to provide a fluid seal through the plate stack.

9. The heat transfer assembly of claim 1, wherein the thermal bridge includes a fluid barrier to provide a fluid seal between the thermal bridge and the cold plate.

10. The heat transfer assembly of claim 1, wherein the thermal bridge includes a fluid barrier through an interior of the thermal bridge to seal the fluid cavity.

11. The heat transfer assembly of claim 10, wherein the fluid barrier includes a solder layer soldered to the plates in the plate stack.

12. The heat transfer assembly of claim 1, wherein the thermal bridge including an upper bridge assembly thermally coupled to the cold plate, a lower bridge assembly configured to be thermally coupled to an electrical component, and a spring element between the upper bridge assembly and the lower bridge assembly allowing expansion and compression of the thermal bridge, the upper bridge assembly including a plurality of upper plates arranged in an upper plate stack, each upper plate having an inner end and an outer end, the outer ends of the upper plates forming an upper thermal interface, the upper bridge assembly extending through the cold plate body with the upper thermal interface exposed in the fluid cavity for interfacing with the coolant, the lower bridge assembly including a plurality of lower plates arranged in a lower plate stack, each lower plate having an inner end and an outer end, the outer ends of the lower plates configured to face and thermally couple to the electrical component, sides of the lower plates facing sides of the upper plates to thermally interface the lower plates with the upper plates, the spring element including an upper spring member engaging the inner ends of the upper plates and a lower spring member engaging the inner ends of the lower plates to bias the lower plates with an opening force generally away from the upper plates.

13. A heat transfer assembly comprising:
a cold plate including a cold plate body forming a fluid cavity configured to receive coolant, the cold plate including a fluid inlet and a fluid outlet in flow communication with the fluid cavity; and
a thermal bridge coupled to the cold plate, the thermal bridge including an upper bridge assembly thermally coupled to the cold plate, a lower bridge assembly configured to be thermally coupled to an electrical component, and a spring element between the upper bridge assembly and the lower bridge assembly allowing expansion and compression of the thermal bridge;
the upper bridge assembly including a plurality of upper plates arranged in an upper plate stack, each upper plate having a front end and a rear end, each upper plate having sides between the front end and the rear end, each upper plate having an inner end and an outer end, the outer ends of the upper plates forming an upper thermal interface, the upper bridge assembly extending through the cold plate body with the upper thermal interface exposed in the fluid cavity for interfacing with the coolant;
the lower bridge assembly including a plurality of lower plates arranged in a lower plate stack, each lower plate having a front end and a rear end, each lower plate having sides between the front end and the rear end, each lower plate having an inner end and an outer end, the outer ends of the lower plates configured to face and thermally couple to the electrical component, the sides of the lower plates facing the sides of the upper plates to thermally interface the lower plates with the upper plates; and
the spring element including an upper spring member engaging the upper plates and a lower spring member engaging the lower plates to bias the lower plates with an opening force generally away from the upper plates.

14. The heat transfer assembly of claim 13, wherein the upper plates include upper interface plates and upper spacer plates between the upper interface plates, the lower plates including lower interface plates and lower spacer plates between the lower interface plates, the sides of the upper interface plates overlapping and facing the sides of the lower interface plates to thermally interface the lower plates with the upper plates.

15. The heat transfer assembly of claim 14, wherein upper portions of the upper interface plates and/or the upper spacer plates form fluid transfer portions, the fluid transfer portions located in the fluid cavity in flow communication with the coolant.

16. The heat transfer assembly of claim 15, wherein the thermal bridge includes fluid channels between the fluid transfer portions, the fluid channels configured to receive the coolant flowing between the fluid inlet in the fluid outlet.

17. The heat transfer assembly of claim 13, wherein the thermal bridge includes a thermal bridge frame surrounding the upper bridge assembly and the lower bridge assembly to hold the upper plates in the upper plate stack and the lower plates in the lower plate stack.

18. The heat transfer assembly of claim 13, wherein the upper plate stack includes a wet portion in the fluid cavity in fluid communication with the coolant and a dry portion outside of the fluid cavity isolated from the coolant.

19. The heat transfer assembly of claim 13, wherein the upper bridge assembly includes a fluid barrier to provide a fluid seal through the upper plate stack.

20. A communication system comprising:
an electrical component including a thermal surface; and
a heat transfer assembly thermally coupled to the thermal surface to dissipate heat from the electrical component, the heat transfer assembly including a cold plate and a thermal bridge coupled to the cold plate, the cold plate including a cold plate body forming a fluid cavity configured to receive coolant, the cold plate including a fluid inlet and a fluid outlet in flow communication with the fluid cavity, the thermal bridge including an upper thermal interface and a lower thermal interface, the thermal bridge including a plurality of interleaved plates arranged in a plate stack with the plates being movable relative to each other in the plate stack, the lower thermal interface configured to be in thermal communication with the thermal surface of the electrical component to dissipate heat from the electrical component, the thermal bridge extending through the cold plate body with the upper thermal interface exposed in the fluid cavity for interfacing with the coolant.
